(19) United States
(12) Patent Application Publication
(10) Pub. No.: US 2023/0420325 A1
(43) Pub. Date: Dec. 28, 2023

(54) THERMAL PAD STRUCTURES FOR LED PACKAGES WITH REDUCED SIZES

(71) Applicant: CreeLED, Inc., Durham, NC (US)

(72) Inventors: Robert Wilcox, Rolesville, NC (US); Colin Blakely, Raleigh, NC (US)

(21) Appl. No.: 17/809,132

(22) Filed: Jun. 27, 2022

(51) Int. Cl. H01L 23/34; H01L 33/62

(52) U.S. Cl. CPC H01L 23/34; H01L 33/62

(57) ABSTRACT

Light-emitting diode (LED) packages and more particularly thermal pad structures for LED packages with reduced sizes are disclosed. LED packages include an LED chip on a submount with an anode mounting pad, a cathode mounting pad, and a thermal pad on an opposite side of the submount to the LED chip. Structures of thermal pads and corresponding anode and cathode mounting pads include arrangements that provide shortest distances values between the thermal pads and the anode and cathode mounting pads that provide increased surface area for heat dissipation while also reducing electrical shorting, particularly for submounts with compact sizes.

### FIELD OF THE DISCLOSURE

The present disclosure relates to light-emitting diode (LED) packages, and more particularly to thermal pad structures for LED packages with reduced sizes.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new display applications and are being increasingly utilized for general illumination applications, often replacing incandescent and fluorescent light sources.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from silicon carbide, gallium nitride, gallium phosphide, indium phosphide, aluminum nitride, gallium arsenide-based materials, and/or from organic semiconductor materials. Photons generated by the active region are initiated in all directions.

LED chips are typically housed in LED packages that provide mechanical support and electrical connections to LED chips. As demands of modern LED applications are continually requiring miniaturization of LED packages, challenges exist in producing high quality light with desired emission characteristics while also providing high light emission efficiency in compact LED packages.

The art continues to seek improved LEDs and solid-state lighting devices having desirable illumination characteristics capable of overcoming challenges associated with conventional LED devices.

### SUMMARY

The present disclosure relates to light-emitting diode (LED) packages, and more particularly to thermal pad structures for LED packages with reduced sizes. LED packages include an LED chip on a submount with an anode mounting pad, a cathode mounting pad, and a thermal pad on an opposite side of the submount to the LED chip. Structures of thermal pads and corresponding anode and cathode mounting pads include arrangements that provide shortest distances values between the thermal pads and the anode and cathode mounting pads that provide increased surface area for heat dissipation while also reducing electrical shorting, particularly for submounts with compact sizes.

In one aspect, an LED package comprises: a submount comprising a first side and a second side that opposes the first side; an LED chip on the first side of the submount; an anode mounting pad and a cathode mounting pad on the second side of the submount, the anode mounting pad and the cathode mounting pad being electrically coupled to the LED chip; and a thermal pad on the second side of the submount, the thermal pad arranged between the anode mounting pad and the cathode mounting pad on the second side such that a shortest distance between the thermal pad and the anode mounting pad or the cathode mounting pad is in a range from 125 microns (μm) to 325 μm. In certain embodiments, the anode mounting pad comprises a first anode pad proximate a first corner of the submount, a second anode pad proximate a second corner of the submount, and an anode extension that electrically couples the first anode pad to the second anode pad. In certain embodiments, a width of the anode extension is narrower than widths of the first anode pad and the second anode pad. In certain embodiments, the cathode mounting pad comprises a first cathode pad proximate a third corner of the submount, a second cathode pad proximate a fourth corner of the submount, and a cathode extension that electrically couples the first cathode pad to the second cathode pad. In certain embodiments, the thermal pad comprises a first protrusion that extends on the second side in a first direction toward the anode extension and a second protrusion that extends on the second side in a second direction toward a gap formed between the first anode pad and the first cathode pad. In certain embodiments, a portion of the second protrusion is arranged between the first anode pad and the first cathode pad. In certain embodiments, the thermal pad forms a circular shape on the second side and the shortest distance is formed between the thermal pad and the first and second anode pads or between the thermal pad and the first and second cathode pads. In certain embodiments, the thermal pad forms a circular shape on the second side and the shortest distance is formed between the thermal pad and anode extension or between the thermal pad and the cathode extension. In certain embodiments, the submount comprises a length and a width that are both less than 2 millimeters (mm). In certain embodiments, the length and the width are in a range from 1 mm to less than 2 mm. The LED package may further comprise: an anode metal trace and a cathode metal trace on the first side of the submount that are electrically coupled with the LED chip; a first via that extends through the submount to electrically couple the anode metal trace to the anode mounting pad; and a second via that extends through the submount to electrically couple the cathode metal trace to the cathode mounting pad; wherein the first via and the second via extend through portions of the submount that are outside peripheral edges of the LED chip. The LED package may further comprise a third via that extends through the submount between the thermal pad and the LED chip. In certain embodiments, the third via extends through an entire thickness of the submount. In certain embodiments, the third via extends through less than an entire thickness of the submount. In certain embodiments, the shortest distance between the thermal pad and the anode mounting pad or the cathode mounting pad is in a range from 175 μm to 275 μm.

In another aspect, an LED package comprises: a submount comprising a first side and a second side that opposes the first side, the submount comprising a length and a width that are both less than 2 mm; an LED chip on the first side of the submount; an anode mounting pad and a cathode mounting pad on the second side of the submount, the anode mounting pad and the cathode mounting pad being electrically coupled to the LED chip; and a thermal pad on the second side of the submount such that a shortest distance between the thermal pad and the anode mounting pad is in a range from 125 μm to 325 μm and a shortest distance between the thermal pad and the cathode mounting pad is in a range from 125 μm to 325 μm. In certain embodiments, the submount forms a rectangular shape such that a length of the submount is greater than a width of the submount; the thermal pad extends on the second side from a center location toward a first edge of the submount; and the anode mounting pad and the cathode mounting pad are proximate a second edge of the submount that is opposite the first edge. In certain embodiments, the thermal pad forms a circular shape on the second side of the submount; the shortest distance between the thermal pad and the anode mounting pad is formed between the thermal pad and a corner of the anode mounting pad; and the shortest distance between the thermal pad and the cathode mounting pad is formed between the thermal pad and a corner of the cathode mounting pad. In certain embodiments, the thermal pad comprises a protrusion that extends on the second side in a second direction toward a gap formed between the anode mounting pad and the cathode mounting pad. In certain embodiments, at least one edge of the anode mounting pad is parallel to an edge of the protrusion and at least one edge of the cathode mounting pad is parallel to another edge of the protrusion. In certain embodiments, the shortest distance between the thermal pad and the anode mounting pad is formed between an edge of the protrusion and the anode mounting pad; and the shortest distance between the thermal pad and the cathode mounting pad is formed between another edge of the protrusion and the cathode mounting pad.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a top view of a light-emitting diode (LED) package that includes an LED chip mounted on a submount according to principles of the present disclosure.

FIG. 1B is a bottom view of the LED package of FIG. 1A illustrating an arrangement of anode and cathode mounting pads and a thermal pad.

FIG. 1C is a cross-sectional view of the LED package of FIG. 1A taken along the sectional line 1C-1C of FIG. 1A.

FIG. 1D is a cross-sectional view of the LED package of FIG. 1C with an alternative arrangement for the via.

FIG. 1E is a cross-sectional view of the LED package of FIG. 1A taken along the sectional line 1E-1E of FIG. 1A.

FIG. 2 is bottom view of an LED package that is similar to the LED package of FIG. 1A for embodiments where the via registered with the thermal pad of FIG. 1A is omitted.

FIG. 3 is bottom view of an LED package that is similar to the LED package of FIG. 1A for another arrangement of the thermal pad where second protrusions extend farther on the submount.

FIG. 4 is bottom view of an LED package that is similar to the LED package of FIG. 3 for embodiments where the via registered with the thermal pad of FIG. 3 is omitted.

FIG. 5 is bottom view of an LED package that is similar to the LED package of FIG. 1A for a circular arrangement of the thermal pad.

FIG. 6 is bottom view of an LED package that is similar to the LED package of FIG. 5 for embodiments where the via registered with the thermal pad of FIG. 5 is omitted.

FIG. 7 is a bottom view of an LED package that is similar to the LED package of FIGS. 1A to 1E for embodiments where the thermal pad extends from a center location toward one edge of the submount and the anode and cathode mounting pads are arranged proximate an opposing edge of the submount.

FIG. 8 is a bottom view of an LED package that is similar to the LED package of FIG. 7 for embodiments where a first protrusion of the thermal pad extends across the submount in a direction that is oriented between the anode and cathode mounting pads.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to light-emitting diode (LED) packages, and more particularly to thermal pad structures for LED packages with reduced sizes. LED packages include an LED chip on a submount with an anode mounting pad, a cathode mounting pad, and a thermal pad on an opposite side of the submount to the LED chip. Structures of thermal pads and corresponding anode and cathode mounting pads include arrangements that provide shortest distances values between the thermal pads and the anode and cathode mounting pads that provide increased surface area for heat dissipation while also reducing electrical shorting, particularly for submounts with compact sizes.

Before delving into specific details of various aspects of the present disclosure, an overview of various elements that may be included in exemplary LED packages of the present disclosure is provided for context. LED packages may include one or more elements, such as lumiphoric materials, encapsulants, light-altering materials, lenses, and electrical contacts, among others, that are provided along with one or more LED chips. In certain aspects, an LED package may include a support member, such as a submount. Suitable materials for the submount include, but are not limited to, ceramic materials such as aluminum oxide or alumina, AlN, or organic insulators like polyimide (PI) and polyphthalamide (PPA). In other embodiments, a submount may comprise a printed circuit board (PCB), sapphire, Si or any other suitable material. For PCB embodiments, different PCB types can be used such as standard FR-4 PCB, metal core PCB, or any other type of PCB. Encapsulants may be formed to cover LED chips on submounts to provide protection of underlying LED package elements and sometimes provide light shaping of emissions from LED packages. Encapsulants may include materials that are light-transmissive and/or light-transparent to wavelengths provided of underlying LED chips and/or lumiphoric materials. Suitable encapsulant materials include silicones, plastics, epoxies or glass. In certain aspects, encapsulants may include lens shapes for controlling light emissions.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective). In the case of ultraviolet (UV) LEDs, appropriate materials may be selected to provide a desired, and in some embodiments high, reflectivity and/or a desired, and in some embodiments low, absorption. In certain embodiments, a “light-transmissive” material may be configured to transmit at least 50% of emitted radiation of a desired wavelength.

Lumiphoric materials, such as phosphors, may be arranged such that at least some of the light from LED chips is absorbed by the lumiphoric materials and is converted to one or more different wavelengths. A LED package may include an LED chip and one or more recipient lumiphoric materials that may be selected so that their combined output results in light with one or more desired characteristics such as color, color point, intensity, spectral density, etc. In certain embodiments, aggregate emissions of LED chips, optionally in combination with one or more lumiphoric materials, may be arranged to provide cool white, neutral white, or warm white light, such as within a color temperature range of 2500 Kelvin (K) to 10,000 K. In certain embodiments, lumiphoric materials having cyan, green, amber, yellow, orange, and/or red peak wavelengths may be used. Exemplary lumiphoric materials may include yellow (e.g., YAG:Ce), green (e.g., LuAg:Ce), and red (e.g., Ca_{i-x-y}SrₓEu_{y}AlSiN₃) emitting phosphors, and combinations thereof, although many other colors are possible. In certain embodiments, the LED chip and corresponding lumiphoric material may be configured to primarily emit converted light from the lumiphoric material so that aggregate emissions include little to no perceivable emissions that correspond to the LED chip itself.

Light-altering materials may be arranged within LED packages to reflect or otherwise redirect light from the one or more LED chips in a desired emission direction or pattern. Light-altering materials may include many different materials including light-reflective materials that reflect or redirect light, light-absorbing materials that absorb light, and materials that act as a thixotropic agent. As used herein, the term “light-reflective” refers to materials or particles that reflect, refract, scatter, or otherwise redirect light. For light-reflective materials, the light-altering material may include at least one of fused silica, fumed silica, titanium dioxide (TiO₂), or metal particles suspended in a binder, such as silicone or epoxy. For light-absorbing materials, the light-altering material may include at least one of carbon, silicon, or metal particles suspended in a binder, such as silicone or epoxy. The light-reflective materials and the light-absorbing materials may comprise nanoparticles. In certain embodiments, the light-altering material may comprise a generally white color to reflect and redirect light. In other embodiments, the light-altering material may comprise a generally opaque color, such as black or gray for absorbing light and increasing contrast. In certain embodiments, the light-altering material includes both light-reflective material and light-absorbing material suspended in a binder.

The principles of the present disclosure are applicable to LED packages for many different types of LED chips that are configured to emit different wavelengths of light. In certain embodiments, LED chips may be configured to emit blue light with a peak wavelength range of approximately 430 nanometers (nm) to 480 nm. In other embodiments, LED chips may be configured to emit green light with a peak wavelength range of 500 nm to 570 nm. In other embodiments, LED chips may be configured to emit orange and/or red light with a peak wavelength range of 600 nm to 700 nm. In certain embodiments, LED chips may be configured to emit light that is outside the visible spectrum, including one or more portions of the UV spectrum, the infrared (IR) or near-IR spectrum. The UV spectrum is typically divided into three wavelength range categories denotated with letters A, B, and C. In this manner, UV-A light is typically defined as a peak wavelength range from 315 nm to 400 nm, UV-B is typically defined as a peak wavelength range from 280 nm to 315 nm, and UV-C is typically defined as a peak wavelength range from 100 nm to 280 nm. UV LEDs are of particular interest for use in applications related to the disinfection of microorganisms in air, water, and surfaces, among others. In other applications, UV LEDs may also be provided with one or more lumiphoric materials to provide LED packages with aggregated emissions having a broad spectrum and improved color quality for visible light applications. Near-IR and/or IR wavelengths for LED structures of the present disclosure may have wavelengths above 700 nm, such as in a range from 700 nm to 1000 nm, or more.

The present disclosure can be useful for LED packages with LED chips having a variety of geometries, such as vertical geometry or lateral geometry. A vertical geometry LED chip typically includes anode and cathode connections on opposing sides or faces of the LED chip. A lateral geometry LED chip typically includes both anode and cathode connections on the same side of the LED chip that is opposite a substrate, such as a growth substrate. In certain embodiments, a lateral geometry LED chip may be mounted on a submount of an LED package such that the anode and cathode connections are on a face of the LED chip that is opposite the submount. In this configuration, wire bonds may be used to provide electrical connections with the anode and cathode connections. In other embodiments, a lateral geometry LED chip may be flip-chip mounted on a surface of a submount of an LED package such that the anode and cathode connections are on a face of the active LED structure that is adjacent to the submount. In this configuration, electrical traces or patterns may be provided on the submount for providing electrical connections to the anode and cathode connections of the LED chip. In a flip-chip configuration, the active LED structure is configured between the substrate of the LED chip and the submount for the LED package. Accordingly, light emitted from the active LED structure may pass through the substrate in a desired emission direction. In other embodiments, an active LED structure may be bonded to a carrier submount, and the growth substrate may be removed such that light may exit the active LED structure without passing through the growth substrate.

Submounts for LED packages typically include an LED chip mounted on a first side, or topside, of the submount and the LED chip is electrically coupled with corresponding anode and cathode electrical traces on the first side. A second side, or backside, of the submount may include anode and cathode mounting pads that are respectively coupled to the anode and cathode electrical traces on the first side. When electrically activated, the LED chip may generate heat that if not properly dissipated may increase operating temperatures of the LED chip to levels that degrade performance. In this manner, the submount may be configured to dissipate heat away from the LED chip to maintain a suitable operating temperature. For example, the submount may include a material with sufficient thermally conductivity. Additionally, the submount may include a thermal pad on the second side, or backside, that may be thermally coupled to an external thermal path, such as a heatsink, when the LED package is mounted. The thermal pad may be electrically isolated from the anode and cathode mounting pads on the second side.

For large area LED packages, such as those with submount length and width dimensions of 2 mm by 2 mm or greater, the thermal pad generally occupies a large area of the second side. However, for LED packages with smaller dimensions, such as those with lengths and widths below 2 mm by 2 mm, second sides of submounts are typically devoid of thermal pads. This is because the required surface area occupied by the anode and cathode mounting pads to make suitable electrical connections is large relative to the small area of the second side. In this manner, conventional LED packages with smaller dimensions typically have the anode and cathode mounting pads to substantially cover the second side to provide both electrical connections to the LED chips and increase thermal spreading. However, as LED chips are increasingly being developed with higher light outputs, conventional LED package arrangements may not be sufficient to maintain suitable operating temperatures. According to aspects of the present disclosure, LED package structures with backsides that include dedicated thermal pad structures and electrical mounting pads are disclosed that overcome the deficiencies of conventional devices.

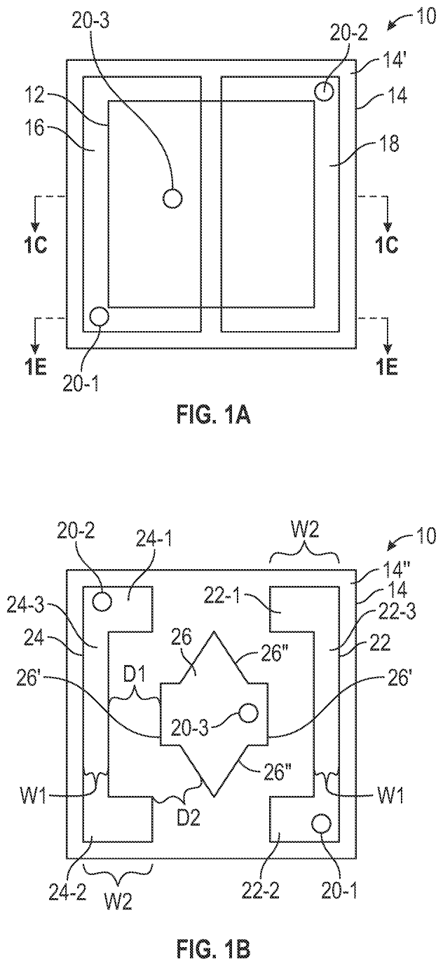

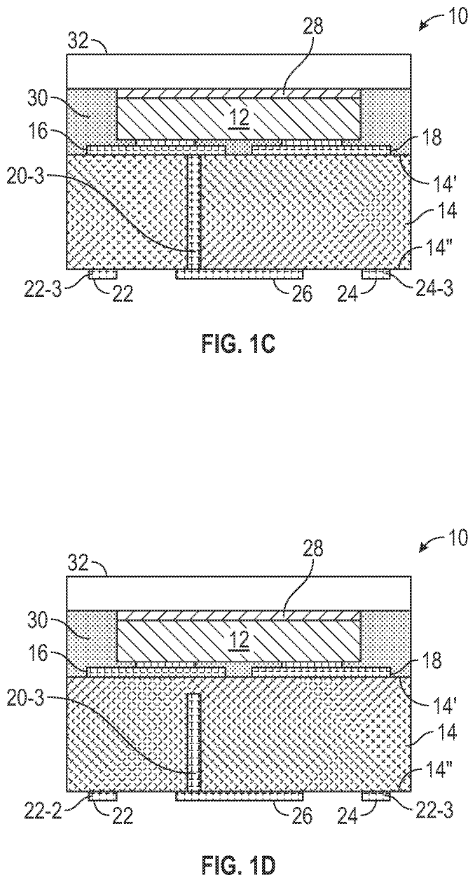

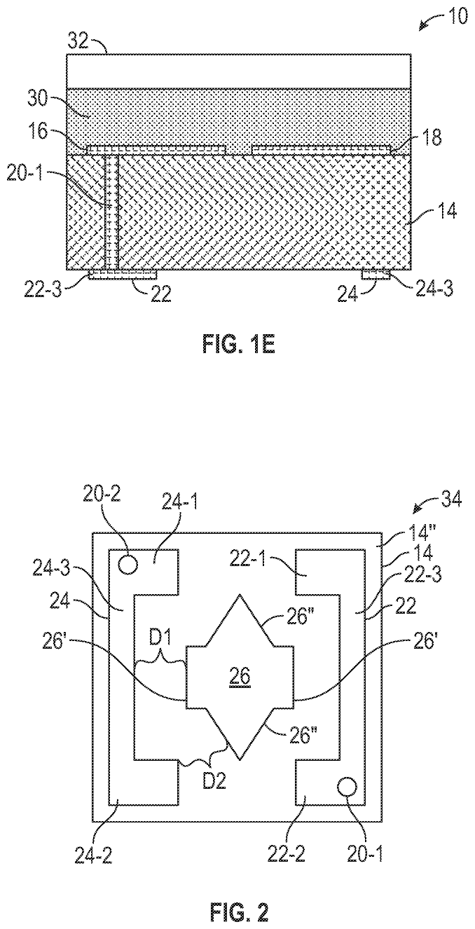

FIG. 1A is a top view of an LED package 10 that includes an LED chip 12 mounted on a submount 14 according to principles of the present disclosure. For illustrative purposes, the LED chip 12 is drawn as transparent to view underlying portions of the LED package 10. An anode metal trace 16 and a cathode metal trace 18 are arranged on a first side 14′ of the submount 14 for providing electrical connections to the LED chip 12. The anode and cathode metal traces 16, 18 may include any number of metals and/or metal layers, including copper (Cu), nickel (Ni), palladium (Pd), gold (Au), or alloys thereof, among others that are patterned on the submount 14. In FIG. 1A, the LED chip 12 is flip-chip mounted on the anode and cathode metal traces 16, 18. For other chip orientations, the LED chip 12 could be mounted to one of the anode and cathode metal traces 16, 18 and wirebonded to the other. A number of vias 20-1 to 20-3 may be arranged within the submount 14 to provide electrical and/or thermal pathways away from the first side 14′. In FIG. 1A, the vias 20-1 and 20-2 may be electrically coupled respectively with the anode and cathode metal traces 16, 18. In certain embodiments, the vias 20-1, 20-2 may be arranged in portions of the submount 14 that are outside peripheral edges of the LED chip 12 to avoid any irregularities, such as nonplanar surfaces, that may form due to differences in coefficients of thermal expansion (CTE) between the vias 20-1, 20-2 and the submount 14. As will be later described in greater detail, the via 20-3 may be electrically isolated from the anode and cathode metal traces 16, 18 and may serve to provide a thermally conductive path through the submount 14. In other embodiments, the via 20-3 may be electrically coupled to one of the anode and cathode metal traces 16, 18 and electrically isolated from the other. In certain embodiments, the via 20-3 is optional and may be omitted.

FIG. 1B is a bottom view of the LED package 10 of FIG. 1A illustrating an arrangement of anode and cathode mounting pads 22, 24 and a thermal pad 26. The bottom view provided in FIG. 1B is from a perspective of a second side 14″, or bottom side, of the submount 14 that is opposite the first side 14′ of FIG. 1A. In FIG. 1B, the view provided is after LED package 10 of FIG. 1A has been rotated upside down from right to left. The thermal pad 26 and the anode and cathode mounting pads 22, 24 may comprise the same or similar materials as described above for the anode and cathode metal traces 16, 18. The anode mounting pad 22 is electrically coupled to the anode metal trace 16 while the cathode mounting pad 24 is electrically coupled to the cathode metal trace 18.

The thermal pad 26 is arranged between the anode and cathode mounting pads 22, 24 on the second side 14″. In this manner, the thermal pad 26 is centrally located on the second side 14″ in a position that is vertically registered with the LED chip 12 on the first side 14′. The anode mounting pad 22 may include two anode pads 22-1, 22-2 and an extension 22-3 therebetween. The anode pads 22-1, 22-2 are arranged proximate two corners of the submount 14, and the extension 22-3 electrically couples the two anode pads 22-1, 22-2 together. In this manner, the two anode pads 22-1, 22-2 and the extension 22-3 may by continuously formed of a same metal trace. As illustrated, the extension 22-3 extends proximate a peripheral edge of the submount 14 between the corners associated with the anode pads 22-1, 22-2. The extension 22-3 may be formed with a first width W1 that is narrower than a second width W2 of the anode pads 22-1, 22-2. The cathode mounting pad 24 may include two cathode pads 24-1, 24-2 and an extension 24-3 therebetween with a similar arrangement including the first and second widths W1, W2 as described for the anode mounting pad 22. The second widths W2 are larger to ensure suitable electrical contact with connections of a surface that the LED package 10 may be mounted to. The second widths W2 may also be suitable to provide contact points for electrical testing of the LED package 10. For example, the second widths W2 of the anode pads 22-1, 22-2 and the cathode pads 24-1, 24-2 may be sized to accommodate automated electrical testing, such as four-pin testing. Specifically, the second widths W2 may be sized to allow for machine tolerances of probe tips that electrically contact the anode pads 22-1, 22-2 and the cathode pads 24-1, 24-2 during testing.

As illustrated, the thermal pad 26 includes a shape that is arranged based on the shapes of the anode and cathode mounting pads 22, 24. For example, the thermal pad 26 may include first protrusions 26′ that laterally extend on the second side 14″ toward the extensions 22-3, 24-3 and second protrusions 26″ that laterally extend on the second side 14″ in directions toward gaps formed between the anode pads 22-1, 22-2 and the cathode pads 24-1, 24-2. In doing so, a shortest distance across the submount 14 between any edge of the thermal pad 26 and the anode mounting pad 22 or the cathode mounting pad 24 is in a range from 125 microns (μm) to 325 μm, or in a range from 125 μm to 300 μm, or in a range from 125 μm to 275 μm, or in a range from 200 μm to 275 μm. In this manner, the thermal pad 26 may maintain suitable spacing to avoid electrical shorting with the anode and cathode mounting pads 22, 24 while also including the protrusions 26′, 26″ that increase surface area of the thermal pad 26. Such arrangements may be well suited for increasing thermal dissipation capabilities without electrical shorting when the LED package 10 is formed with a small size or footprint, such as length and width dimensions of the submount 14 of FIG. 1B that are less than 2 mm by 2 mm. In specific examples, the 14 may have length and width dimensions that are 1.4 mm by 1.4 mm, or 1.6 mm by 1.6 mm, or in a range from 1 mm to less than 2 mm for both the length and width. Depending on the geometry of the LED package 10, different ones of the shortest distance ranges described above may provide lower failure rates in manufacturing and/or operation. For example, when the length and width of the submount 14 are less than 2 mm, for example 1.4 mm by 1.4 mm or 1.6 mm by 1.6 mm, a range from 175 μm to 275 μm may embody a suitable range with highest manufacturing yields that reduces electrical shorting while also providing increased surface area of the thermal pad 26.

In the example illustrated in FIG. 1B, a first distance D1 may define a shortest distance with any of the above-specified values between the cathode mounting pad 24 (i.e., the extension 24-3) and the thermal pad 26 at one of the first protrusions 26′. A second distance D2 may define a shortest distance with any of the above-specified values between the cathode mounting pad 24 (i.e., the cathode pads 24-1, 24-2) and the thermal pad 26 proximate one of the second protrusions 26″. While only drawn in the context of the cathode mounting pad 24, the first and second distances D1 and D2 are also applicable to shortest distances between the thermal pad 26 and the anode mounting pad 22. In certain embodiments, the first and second distances D1 and D2 may be the same, while in other embodiments, the first and second distances D1 and D2 may differ within any of the above-specified ranges for the shortest distance defined above.

FIG. 1C is a cross-sectional view of the LED package 10 of FIG. 1A taken along the sectional line 1C-1C of FIG. 1A. As illustrated, the via 20-3 extends between the anode metal trace 16 and the thermal pad 26 from a position that is vertically registered with the LED chip 12. In this manner, the via 20-3 forms a thermal path for dissipation of heat through the submount 14 and to the thermal pad 26. In certain embodiments, the via 20-3 may electrically couple the anode metal trace 16 to the thermal pad 26 as long as the thermal pad 26 remains electrically isolated from the cathode metal trace 18 and the cathode mounting pad 24. In other embodiments, the via 20-3 may alternatively be formed between the thermal pad 26 and the cathode metal trace 18 as long as the via 20-3 is electrically isolated from the anode metal trace 16 and the anode mounting pad 22. As further illustrated in FIG. 1C, certain embodiments may include a layer of lumiphoric material 28 on the LED chip 12. Additionally, a light-altering material 30 may be arranged around peripheral edges of the LED chip 12 to redirect light in a desired emission direction. Finally, an encapsulant 32 may be provided over the LED chip 12. In various configurations of the LED package 10, one or more of the lumiphoric material 28 and the light-altering material 30 may be omitted without deviating from the principles disclosed.

FIG. 1D is a cross-sectional view of the LED package 10 of FIG. 1C with an alternative arrangement for the via 20-3. As illustrated, the via 20-3 may be vertically registered with the LED chip 12 to provide a thermal path through the submount 14 without electrically coupling the thermal pad 26 to either the anode or cathode metal traces 16, 18. For example, the via 20-3 may not extend entirely through the submount 14 such that portions of the submount 14 are arranged between the first side 14′ and the via 20-3. In certain embodiments, portions of the submount 14 may be arranged between the second side 14″ and the thermal pad 26.

FIG. 1E is a cross-sectional view of the LED package 10 of FIG. 1A taken along the sectional line 1E-1E of FIG. 1A. In this manner, the view of FIG. 1A is proximate edges of the LED package 10 that are outside the LED chip 12. The via 20-1 is arranged to extend through an entire thickness of the submount 14 to provide electrical coupling between the anode metal trace 16 and the anode mounting pad 22. Turning back to FIGS. 1A and 1B, the via 20-2 is arranged to provide electrical coupling between the cathode metal trace 18 and the cathode mounting pad 24 in a similar manner as illustrated for the via 20-1 of FIG. 1E.

FIG. 2 is bottom view of an LED package 34 that is similar to the LED package 10 of FIG. 1A for embodiments where the via 20-3 of FIG. 1A is omitted. All other elements of the LED package 34 may be the same as described above for the LED package 10 of FIGS. 1A to 1E. In certain embodiments, the arrangement of the thermal pad 26 relative to the anode and cathode mounting pads 22, 24 as described above may provide sufficient thermal management for the LED package 34. By omitting the via 20-3 of FIGS. 1A to 1E, all vias 20-1, 20-2 may be arranged outside peripheral edges of the LED chip 12 (see FIG. 1A). Accordingly, any irregularities, such as nonplanar surfaces, attributed to differences in CTE between the vias 20-1, 20-2 and the submount 14 may be outside LED chip mounting areas.

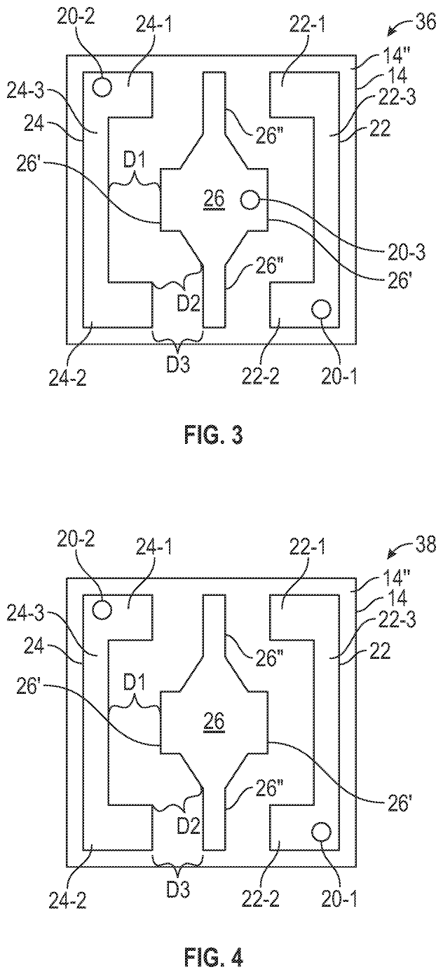

FIG. 3 is bottom view of an LED package 36 that is similar to the LED package 10 of FIG. 1A for another arrangement of the thermal pad 26 where the second protrusions 26″ extend farther on the submount 14. All other elements of the LED package 36 may be the same as described above for the LED package of FIGS. 1A to 1E. As illustrated in FIG. 3, the second protrusions 26″ may extend such that portions of the second protrusions 26″ are arranged between the anode pads 22-1, 22-2 and the cathode pads 24-1, 24-2 and the anode and cathode mounting pads 22, 24. In this manner, a third distance D3 may defined as a shortest distance between the second protrusions 26″ and both the anode pads 22-1, 22-2 and the cathode pads 24-1, 24-2. The third distance D3 may be provided in a similar manner to the first and second distances D1 and D2 described above. For example, all of the first, second, and third distances D1 to D3 may be within a range from 125 μm to 325 μm, or in a range from 125 μm to 300 μm, or in a range from 125 μm to 275 μm, or in a range from 175 μm to 275 μm, or in a range from 200 μm to 275 μm. Accordingly, the thermal pad 26 may maintain suitable spacing to avoid electrical shorting with the anode and cathode mounting pads 22, 24 while also increasing surface area of the thermal pad 26. Depending on the geometry of the LED package 36, different ones of the ranges may provide lower failure rates in manufacturing. For example, a square package where the length and width of the submount 14 are less than 2 mm, for example 1.4 mm by 1.4 mm or 1.6 mm by 1.6 mm, a range from 175 μm to 275 μm may embody a suitable range with highest manufacturing yields that reduces electrical shorting while also providing increased surface area of the thermal pad 26. In certain embodiments, each of the distances D1 to D3 may have a same value within any of the above-specified ranges. As illustrated, certain embodiments of the LED package 36 may include the via 20-3 as described above.

FIG. 4 is bottom view of an LED package 38 that is similar to the LED package 36 of FIG. 3 for embodiments where the via 20-3 of FIG. 3 is omitted. All other elements of the LED package 38 may be the same as described above for the LED package 36 of FIG. 3. In this manner, the via 20-3 may be omitted for similar reasons described above for the LED package 34 of FIG. 2.

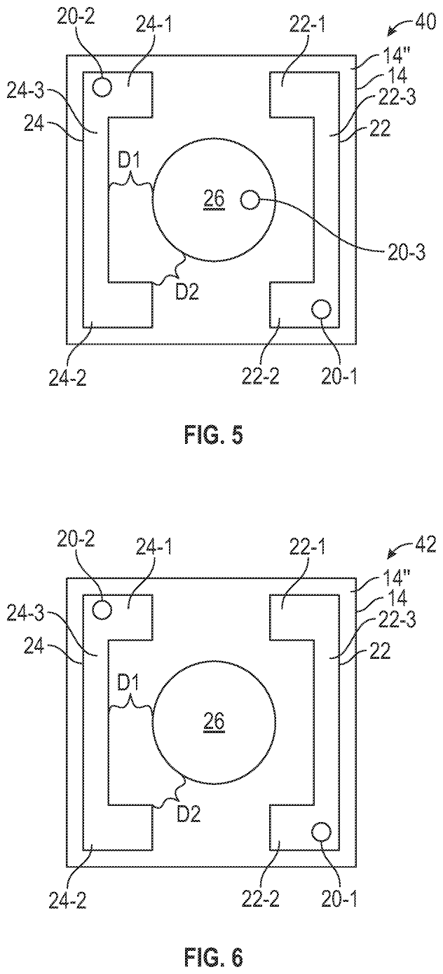

FIG. 5 is bottom view of an LED package 40 that is similar to the LED package 10 of FIG. 1A for a circular arrangement of the thermal pad 26. All other elements of the LED package 40 may be the same as described above for the LED package 10 of FIGS. 1A to 1E. As illustrated in FIG. 5, the thermal pad 26 is circular shaped about a central location of the second side 14″ of the submount 14. In this manner, the thermal pad 26 may radially collect and/or spread heat in a uniform manner. The outside edges of the circular shape of the thermal pad 26 may be arranged such that the first and second distances D1 and D2 maintain the spacings described above for the shortest distance values. As illustrated, the first distance D1 is the shortest distance between the thermal pad 26 and the anode or cathode extensions 22-3, 24-3 while the second distance D2 is the shortest distance between the thermal pad 26 and corners of the anode pads 22-1, 22-2 and/or corners of the cathode pads 24-1, 24-2. As illustrated, certain embodiments of the LED package 40 may include the via 20-3 as described above.

FIG. 6 is bottom view of an LED package 42 that is similar to the LED package 40 of FIG. 5 for embodiments where the via 20-3 of FIG. 5 is omitted. All other elements of the LED package 42 may be the same as described above for the LED package 40 of FIG. 5. Accordingly, the via 20-3 may be omitted for similar reasons described above for the LED package 34 of FIG. 2.

While the above-described embodiments are provided in the context of thermal pads that are centrally arranged between anode and cathode mounting pads on bottom sides of submounts, the principles disclosed are applicable to other arrangements of small footprint LED packages. For example, certain small footprint LED packages, with lengths and widths both below 2 mm, may be provided with rectangular shaped submounts where thermal pads extend from central locations toward one edge of the submount and anode and cathode mounting pads are arranged proximate an opposing edge of the submount.

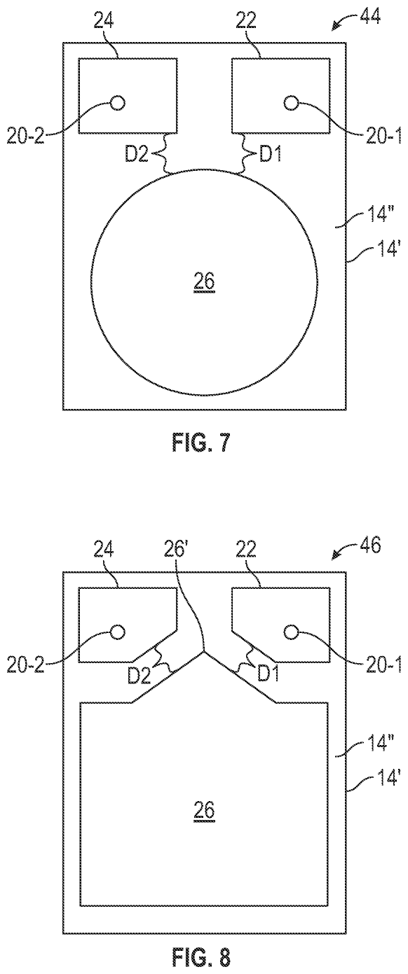

FIG. 7 is a bottom view of an LED package 44 that is similar to the LED package 10 of FIGS. 1A to 1E for embodiments where the thermal pad 26 extends from a center location toward one edge of the submount 14 and the anode and cathode mounting pads 22, 24 are arranged proximate an opposing edge of the submount 14. Such arrangements may be particularly useful for compact sizes for the LED package 44, such as length and width dimensions of the submount 14 both being below 2 mm. In certain embodiments, the submount 14 may have a rectangular shape. For example, longest edges of the submount 14 may be in a range from 1.5 mm to less than 2 mm and shortest edges of the submount 14 may be in a range from 1 mm to less than 1.5 mm. In a specific example, the submount 14 may have length and width dimensions of 1.8 mm by 1.4 mm. In FIG. 7, the thermal pad 26 comprises a circular arrangement in a similar manner to FIG. 5. In this manner, outside edges of the circular shape of the thermal pad 26 may be arranged such that the first and second distances D1 and D2 maintain the spacings described above for the shortest distance values.

FIG. 8 is a bottom view of an LED package 46 that is similar to the LED package 44 of FIG. 7 for embodiments where the first protrusion 26′ of the thermal pad 26 extends across the submount 14 in a direction that is oriented between the anode and cathode mounting pads 22, 24. As illustrated, the anode and cathode mounting pads 22, 24 may be formed with shapes that correspond or otherwise track with portions of the shape of the first protrusion 26′. In FIG. 8, the first protrusion 26′ forms a triangular shape and the anode and cathode mounting pads 22, 24 are each formed with at least one edge that is substantially parallel to corresponding edges of the first protrusion 26′. In this manner, outside edges of the thermal pad 26 along the first protrusion 26′ may be arranged such that the first and second distances D1 and D2 maintain the spacings described above for the shortest distance values. In certain embodiments, the anode and cathode mounting pads 22, 24 may be formed with non-rectangular shapes to accommodate the spacing with the first protrusion 26′. For example, each of the anode and cathode mounting pads 22, 24 may have edges that are parallel with edges of the submount 14 and other edges that are nonparallel with edges of the submount 14 in order to track the shape of the first protrusion 26′.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) package comprising:
a submount comprising a first side and a second side that opposes the first side;
an LED chip on the first side of the submount;
an anode mounting pad and a cathode mounting pad on the second side of the submount, the anode mounting pad and the cathode mounting pad being electrically coupled to the LED chip; and
a thermal pad on the second side of the submount, the thermal pad arranged between the anode mounting pad and the cathode mounting pad on the second side such that a shortest distance between the thermal pad and the anode mounting pad or the cathode mounting pad is in a range from 125 microns (μm) to 325 μm.

2. The LED package of claim 1, wherein the anode mounting pad comprises a first anode pad proximate a first corner of the submount, a second anode pad proximate a second corner of the submount, and an anode extension that electrically couples the first anode pad to the second anode pad.

3. The LED package of claim 2, wherein a width of the anode extension is narrower than widths of the first anode pad and the second anode pad.

4. The LED package of claim 3, wherein the cathode mounting pad comprises a first cathode pad proximate a third corner of the submount, a second cathode pad proximate a fourth corner of the submount, and a cathode extension that electrically couples the first cathode pad to the second cathode pad.

5. The LED package of claim 4, wherein the thermal pad comprises a first protrusion that extends on the second side in a first direction toward the anode extension and a second protrusion that extends on the second side in a second direction toward a gap formed between the first anode pad and the first cathode pad.

6. The LED package of claim 5, wherein a portion of the second protrusion is arranged between the first anode pad and the first cathode pad.

7. The LED package of claim 4, wherein the thermal pad forms a circular shape on the second side and the shortest distance is formed between the thermal pad and the first and second anode pads or between the thermal pad and the first and second cathode pads.

8. The LED package of claim 4, wherein the thermal pad forms a circular shape on the second side and the shortest distance is formed between the thermal pad and anode extension or between the thermal pad and the cathode extension.

9. The LED package of claim 1, wherein the submount comprises a length and a width that are both less than 2 millimeters (mm).

10. The LED package of claim 9, wherein the length and the width are in a range from 1 mm to less than 2 mm.

11. The LED package of claim 1, further comprising:
an anode metal trace and a cathode metal trace on the first side of the submount that are electrically coupled with the LED chip;
a first via that extends through the submount to electrically couple the anode metal trace to the anode mounting pad; and
a second via that extends through the submount to electrically couple the cathode metal trace to the cathode mounting pad;
wherein the first via and the second via extend through portions of the submount that are outside peripheral edges of the LED chip.

12. The LED package of claim 11, further comprising a third via that extends through the submount between the thermal pad and the LED chip.

13. The LED package of claim 12, wherein the third via extends through an entire thickness of the submount.

14. The LED package of claim 12, wherein the third via extends through less than an entire thickness of the submount.

15. The LED package of claim 1, wherein the shortest distance between the thermal pad and the anode mounting pad or the cathode mounting pad is in a range from 175 μm to 275 μm.

16. A light-emitting diode (LED) package comprising:
a submount comprising a first side and a second side that opposes the first side, the submount comprising a length and a width that are both less than 2 millimeters (mm);
an LED chip on the first side of the submount;
an anode mounting pad and a cathode mounting pad on the second side of the submount, the anode mounting pad and the cathode mounting pad being electrically coupled to the LED chip; and
a thermal pad on the second side of the submount such that a shortest distance between the thermal pad and the anode mounting pad is in a range from 125 microns (μm) to 325 μm and a shortest distance between the thermal pad and the cathode mounting pad is in a range from 125 μm to 325 μm.

17. The LED package of claim 16, wherein:
the submount forms a rectangular shape such that a length of the submount is greater than a width of the submount;
the thermal pad extends on the second side from a center location toward a first edge of the submount; and
the anode mounting pad and the cathode mounting pad are proximate a second edge of the submount that is opposite the first edge.

18. The LED package of claim 16, wherein:
the thermal pad forms a circular shape on the second side of the submount;
the shortest distance between the thermal pad and the anode mounting pad is formed between the thermal pad and a corner of the anode mounting pad; and
the shortest distance between the thermal pad and the cathode mounting pad is formed between the thermal pad and a corner of the cathode mounting pad.

19. The LED package of claim 16, wherein the thermal pad comprises a protrusion that extends on the second side in a second direction toward a gap formed between the anode mounting pad and the cathode mounting pad.

20. The LED package of claim 19, wherein at least one edge of the anode mounting pad is parallel to an edge of the protrusion and at least one edge of the cathode mounting pad is parallel to another edge of the protrusion.

21. The LED package of claim 19, wherein:
the shortest distance between the thermal pad and the anode mounting pad is formed between an edge of the protrusion and the anode mounting pad; and
the shortest distance between the thermal pad and the cathode mounting pad is formed between another edge of the protrusion and the cathode mounting pad.
